(19) United States
(12) Patent Application Publication
(10) Pub. No.: US 2026/0250832 A1
(43) Pub. Date: Aug. 27, 2026

(54) IMPROVED CSS DEPOSITION PROCESS

(71) Applicant: Nanofilm Technologies International Limited, Singapore (SG)

(72) Inventors: Xu Shi, Singapore (SG); Guangyi Zhang, Singapore (SG); Yajuan Tan, Singapore (SG); Lars Lieberwirth, Singapore (SG)

(21) Appl. No.: 19/148,547

(22) PCT Filed: Jan. 19, 2024
(86) PCT No.: PCT/EP2024/051234

§ 371 Date: Jul. 16, 2025

(30) Foreign Application Priority Data
Jan. 19, 2023 (EP) 23152517.1

(51) Int. Cl. C23C 14/24; C23C 14/06; C23C 14/54; C23C 14/56

(52) U.S. Cl. CPC C23C 14/246; C23C 14/0629; C23C 14/54; C23C 14/56

(57) ABSTRACT

Apparatus for continuously depositing a coating, optionally a multi-layer coating, onto a substrate by close-spaced sublimation (CSS) of coating source material, comprises a CSS source, for depositing the coating onto the substrate, and a feeder system for feeding coating source material into the CSS source, wherein the feeder system comprises a self-cleaning twin screw feeder arranged to feed the coating source material into the CSS source during deposition of the coating. In depositing a cadmium-containing coating using the apparatus, sensors are located on the source crucible and the method comprises monitoring input from the one or more sensors and adjusting the rate of feeding by the feeder system to maintain a predetermined rate of deposition.

### INTRODUCTION

The present invention relates to coatings deposited using a close-spaced sublimation (CSS) apparatus and methods of depositing coatings using such apparatus.

### BACKGROUND TO THE INVENTION

Close-spaced sublimation (CSS) is a technique used in the production of thin film photovoltaic devices such as CdTe solar cells, in particular for the thin film deposition of the p-type semiconductor CdTe layer and an n-type window layer such as CdS. When using CSS, solid source materials in the form of powder or granules are placed in a crucible or receptacle inside a vacuum chamber. The crucible or receptacle is heated to a high temperature such that the solid source material sublimes, producing vapours that are subsequently deposited onto the substrate surface, disposed close to the vapour exit, forming a thin film.

The source material is consumed and needs to be refilled once it is depleted. There are various ways to replenish the source material. One traditional way is to cool down the system, break vacuum and refill the crucible with the source material. This disrupts the continuous operation of the deposition system as it takes time to pump the system, cool down the machine, and heat up the machine after the crucible has been refilled. Another solution is to add a feeding device to refill the crucible without interrupting the vacuum environment, allowing continuous operation of the coating machines, thus improving the efficiency of production.

U.S. Pat. No. 8,252,117 discloses an automatic feed system and related process for introducing source material to a thin film vapour deposition system. The device comprises a bulk material hopper, an upper dose cup, a lower dose cup, and a transfer mechanism to transfer the source material to the downstream deposition head. The automatic feed system disclosed in U.S. Pat. No. 8,252,117 is, however, complex and not easy to use.

CN 104451551 discloses a feeding device for a thin film vapour deposition system using carrier gas to move the source material powder or granules down its two hoppers and via the transfer mechanism into the crucible located inside the thin film vapour deposition chamber.

The feed system disclosed in CN 104451551 makes use of a carrier gas to effectively move the source material into the crucible. For close-spaced sublimation systems that do not use any carrier gas, the feed system may not work effectively due to the lack of pressure difference created by the carrier gas at different parts of the feed system.

Despite the prior art, continuous deposition processes, which would require auto-feeding of material from ambient conditions to the deposition source in a hot-vacuum chamber, are generally not used. Systematically, a known and satisfactory batch process is conventional, with a large reservoir of material inside the chamber that can last for a certain amount of time before being refilled.

One problem in the potential design of auto-feeding devices, identified herewith by the inventors, relates to gaseous source materials entering the feeding device parts and depositing on the barrels and components, clogging the system and rendering it impossible to operate in a sustainable manner. Another problem, also identified by the inventors herein, is the variability of feed rate into the crucible, leading to variation in vapour generation and a corresponding variation in coating thickness.

Thus, there is a need for continuously operable CSS systems that can deposit coatings with high consistency onto substrates. An aim of the present invention is to provide alternative, preferably improved, such systems.

### SUMMARY OF THE INVENTION

Accordingly, the invention provides apparatus for depositing a coating, optionally a multi-layer coating, onto a substrate by close-spaced sublimation (CSS) of coating source material (typically powder and/or granules), comprising
a CSS source, for depositing the coating onto the substrate, and
a feeder system for feeding coating source material into the CSS source, wherein
the feeder system comprises a screw feeder arranged to feed the coating source material into the CSS source during deposition of the coating.

The apparatus can operate with simultaneous feeding of the coating source material and deposition of the coating; hence the apparatus can provide continuous operation.

The invention also provides deposition methods using the apparatus, for example for depositing a cadmium-containing coating. Embodiments of the apparatus comprise one or more sensors to detect coating source material (e.g. powder) level in a crucible of the source, and the methods can include monitoring input from the one or more sensors and adjusting the rate of feeding by the feeder system to maintain a predetermined rate of deposition by the CSS source. Hence, careful control of deposition rate and constant or near constant source output can be achieved.

### DETAILS OF THE INVENTION

Apparatus of the invention for continuously depositing a coating, optionally a multi-layer coating, onto a substrate by close-spaced sublimation (CSS) of coating source material, comprises
a CSS source, for depositing the coating onto the substrate, and
a feeder system for feeding coating source material into the CSS source, wherein
the feeder system comprises a screw feeder arranged to feed the coating source material into the CSS source during deposition of the coating.

The coating source material is generally powder and/or granules, described in more detail herein. The coating source material is conveniently able to pass through the apparatus without a carrier gas. Hence, the methods of the invention can be carried out without requiring a carrier gas.

The screw feeder may be a single screw or a multi-screw feeder, preferably an assembly of two or more screws that in use have surfaces that counter rotate and have contact with each other. Contact and abrasion between those surfaces results in self-cleaning of material deposited onto screw surfaces. Preferred screw feeders are self-cleaning, and typically comprise a self-cleaning twin screw feeder. Examples of such self-cleaning extruders/feeders are known e.g. from U.S. Pat. Nos. 8,079,747, 8,596,856 and WO 2018/196274, adapted for use at the elevated operating temperatures of the apparatus of the invention. Thus, highly heat resistant materials are used to make the screw feeder, such as nickel-based super alloys, ceramics or fused quartz. Preferred feeders are counterrotating, twin screw feeders.

The screw feeder may be located within a sealable portion of the apparatus, e.g. part of, or adjacent and connected to, a deposition chamber of the CSS source; in use that portion can be evacuated, and the screw feeder operated under vacuum or reduced pressure. Practically, the sealable portion is vacuum sealed and then pumped down to an acceptable operating pressure for the (e.g. connected or integral) CSS source.

The feeder system may comprise a hopper for coating source material (e.g. powder and/or granules) storage, upstream of the screw feeder, wherein the hopper is located within a sealable portion of the apparatus; again, in use that portion can be evacuated, and independently from the other sealable portion containing the screw feeder which feeds into the CSS source, and the hopper can then be under vacuum. The hopper may be made from metal, such as stainless steel.

The hopper may be connected to a coating source material transport system. The transport system may comprise a substantially horizontal barrel and a substantially vertical tube. The barrel may be made from metal, and it is optionally protected by a coating. The barrel may also contain a first or upper screw feeder, in addition to the second or lower screw feeder (which feeds into the source). Output from the hopper may be fed, by the first or upper screw feeder or other source material transport system, to the screw feeder which feeds into the CSS source, referred to here as the second or lower screw feeder.

In embodiments of the invention, the source material transport system, to transport source material from the hopper to the second or lower screw feeder, may comprise a vibrating trough inside a slightly slanted barrel (instead of the first screw). The vibrating mechanism is used to move the source material downstream and towards the second screw feeder.

In other embodiments of the invention, described in more detail below, the apparatus comprises the hopper, a first screw feeder and a second screw feeder, wherein the first screw feeder (part of the coating source material transport system) feeds source material from the hopper to the second screw feeder and the second screw feeder feeds source material into the CSS source. The first screw feeder comprises a single-screw that is upstream of the second screw feeder, further from the heated deposition chamber of the source, and experiences lower temperatures than the second screw feeder; the first screw feeder is suitably made of ceramic or metal, e.g. steel and may be treated with a coating, preferably a ta-C coating.

In combination, the first and second sealable portions of the apparatus, that house, respectively, (i) the hopper and the transport system, and (ii) the second or lower screw feeder, enable isolation of the hopper from the deposition chamber of the apparatus, so that the hopper can be filled from an external source material supply without breaking vacuum or otherwise interfering with the deposition chamber pressure. Deposition can be continuous while source material is fed into the hopper periodically.

In a specific embodiment of the invention, again described below in more detail, the apparatus comprises, in order:
a first vacuum gate,
a hopper for storage of coating source material,
a first screw feeder, preferably a single screw feeder,
a second vacuum gate,
a second screw feeder, preferably a counter-rotating twin screw feeder, and
an output from the second screw feeder,
   wherein
the apparatus further comprises a pump to pump down the apparatus between
the first and second vacuum gates.

The vacuum gates provide for a vacuum seal between respective portions of the apparatus, and the gates may also be referred to as vacuum seals or similar. In use, mid-deposition, the second vacuum gate is closed and deposition is ongoing as the deposition chamber is isolated from sections above that gate; the first vacuum gate is opened, and the hopper is fed, e.g. from above by gravity via a chute or funnel. When the hopper is full the first gate is closed and then the region between the first and second gates is pumped down to operating pressure. Once this is reached, the second gate can be opened so that source material from the hopper can be fed using the first screw feeder towards and into the second screw feeder. At this point the first gate is and remains closed, and hence the first gate maintains the desired operating pressure in the chamber: the crucible can be continuously fed without interrupting the deposition process.

The apparatus may further comprise a container for the coating source material (e.g. coating powder), in which the source material is heated to sublimation temperatures, the container generally being of metal or ceramic and referred to as a crucible. Output from the screw feeder is for delivery of source material into the crucible.

Suitably, the crucible comprises a central/middle pin and the output delivers coating source material (e.g. powder) onto the central pin. As described in the example below, coating source material falls onto the pin and is split into sections or streams and thus distributed into different sides/areas of the crucible rather than into one heap. This assists even spread of coating source material into the crucible prior to sublimation.

Inside the middle pin it is optional to include a heater. Provision of the pin, and inclusion where present of the heater, promotes establishment of a thermal equilibrium for heating coating source material in the high temperature crucible. This helps reduce vapour bursts which can create random variations in the deposition process. The pin may as mentioned help distribute the coating source material into and spread it within the crucible. It has been found that apparatus of the invention comprising a central/middle, optionally heated, pin can provide a very stable, continuous feeding of coating source material into the crucible, avoiding vapour bursts; a stable fill level in the crucible and a consequent stable vapour formation rate promotes homogeneity in the deposition process and reduces variations in thickness of deposited films.

The crucible preferably also comprises one or more sensors to detect the level of coating source material therein. In continuous, steady-state operation, steady feeding into the crucible at the same rate as loss of coating source material by sublimation is desired. The sensor(s) enable feedback of coating source material level to achieve this. A feed control system is preferably provided for varying the rate of feeding of the coating source material, e.g. by varying lower screw rotation speed, into the crucible by the feeder system based on input from the crucible level sensor(s). In combination the sensor(s) and associated control system provide efficient monitoring and control of source vapour output for consistent deposition of coatings.

As mentioned above, the apparatus may comprise a hopper for coating source material storage and may further comprise one or more sensors in the hopper to detect level of coating source material therein. Similarly, this enables control systems to indicate when the hopper needs refilling if the process is to remain continuous.

Apparatus of the invention are believed suitable for a number of different coatings, the apparatus is especially suitable for CSS depositing of a coating comprising a cadmium compound, in particular CdS or CdTe.

The invention provides a method of depositing a cadmium-containing coating, comprising operating an apparatus of the invention as described herein. Typically, the method comprises feeding a cadmium-containing source material into the feeder system of the apparatus and depositing the cadmium-containing source material onto a substrate by CSS.

In a particular embodiment, there is provided a method of depositing a cadmium-containing coating, comprising operating an apparatus of the invention that comprises one or more sensors to detect the level of coating source material in the crucible, the method comprising
monitoring input from the one or more sensors, and
adjusting the rate of feeding by the feeder system to maintain a predetermined rate of deposition by the CSS source.

In another particular embodiment, there is provided a method of depositing a cadmium-containing coating, using an apparatus according to the invention, comprising operating an apparatus of the invention that comprises one or more sensors to detect the level of coating source material in the crucible, the method comprising
monitoring input from the one or more sensors in the crucible, and
using the feed control system to adjust the rate of feeding into the crucible by the feeder system, based on the input from the one or more sensors in the crucible, to maintain a predetermined rate of deposition by the CSS source.

In deposition of coatings onto glass using the apparatus, the glass substrate is heated. The coating source material, e.g. Cadmium sulphide (CdS) and Cadmium Telluride (CdTe) powder is heated to a sublimation temperature, which is higher than the temperature of the glass (under the conditions within the source). The coating source material exits the source as a vapour which contacts and deposits onto the (cooler) glass, forming the coating. In general, the glass should not be overheated such that geometric deformation or damage is caused, and the glass is usually heated to a maximum <600° C., e.g. not more than 550° C., typically from 500 to 550° C. During deposition in the coating section of the apparatus, also referred to as the deposition chamber, the localized glass temperature may get slightly hotter, so the glass exiting that chamber may be a little hotter, possibly up to 570° C. There is a limit due to the thermal expansion limitation/stress inside the glass, and these parameters are known in the art.

During deposition, in embodiments of the invention, the glass substrate may be moved through the apparatus at a speed of at least 200 mm/min, preferably at least 400 mm/min and in some embodiments 600 mm/min or higher. These speeds are in general encountered in existing CSS apparatus. An advantage of the invention is that with continuous operation at high feeding rates increased speeds are possible, with consequently reduced time per sheet coated.

Thickness of the CdS and CdTe layers on glass is not an essential feature of the present invention. In embodiments of the invention, solar panels are made using the apparatus and may have a CdS layer with a thickness of between 150 nm and 250 nm, and a CdTe layer with a thickness of at least 10 times the thickness of the CdS layer. In general, the feeding system of the invention provides for steady and stable vapour production and coating thickness is varied by sublimation temperature rather than feed rate (though feed rate may need to be adjusted according to thickness).

For the respective coatings, sublimation of the coating source material is at slightly different temperatures; inside the source, the crucible temperature of CdS may be about 700° C. and the crucible temperature for CdTe may be less, and may be in the range of 600 to 670° C. These sublimation temperatures are conventional and adjusted in the field according to specific apparatus set ups. Variation in temperature can also be used to adjust deposition rate.

Coating material in powdered form is provided and fed into the source. Suitably the grain size is 200 μm or less, preferably 150 μm or less and more preferably 100 μm or less. In specific embodiments, tested to date, the grain-size is approximately 50-100 μm. However, it is also believed that an even smaller grain size may lead to a more consistent, continuous material feeding and therefore a more stable vapour rate. The grain size is therefore also optionally 80 μm or less, or even 60 μm or less. Grain size is measured using laser diffraction-based methods. Suitable equipment is by Malvern Panalytical (e.g. their Mastersizer 3000® machines). Reference to grain size is reference to the particle size(s) of 90% or more by weight of the particles in the powder.

In other embodiments of the invention, coating source material in granular form is provided and fed into the CSS source. The granule size may range from 100 μm to a few millimeters.

As noted above, auto-feeding CSS machines are known; however, they generally have operating inefficiencies and produce coatings with unacceptable variations in coating thickness. The invention addresses one or more or all of these problems and provides improved apparatus and improved methods using the apparatus.

The use of auto-feeding devices of the present invention in CSS deposition systems overcomes the problem of regular refilling interruptions in the system. Auto-feeding is also believed to improve the homogeneity of the deposition over a long period of production time, allowing more consistent mass production.

Auto-feeding also allows a longer uptime of the coating equipment. This results in higher equipment utilization, increased productivity and lower costs of deposition while also improving the quality, consistency and homogeneity of the deposition.

Known auto-feeding systems do not achieve consistent rates of deposition, and therefore result in uneven coating of the substrate. The following features of specific embodiments of the present invention overcome this problem:
The twin-screw feeder effectively removes the deposited source materials and prevents source material vapours from depositing on the upstream barrels and components. This ensures long-term operation of the production line.
There is no carrier gas needed.
There is accurate control of the rate of material feeding to ensure a stable filling level of the crucible to prevent vapour bursts. This helps to ensure a stable vapour deposition rate. This is done via a combination of sensors and by adjusting the dispense speed from the screw feeders.
Sensors are used to precisely control the amount of material inside the crucible to realise long-term stable coating rate.

### EXAMPLES

The present invention is now described in more specific detail with reference to the accompanying drawings, in which:—

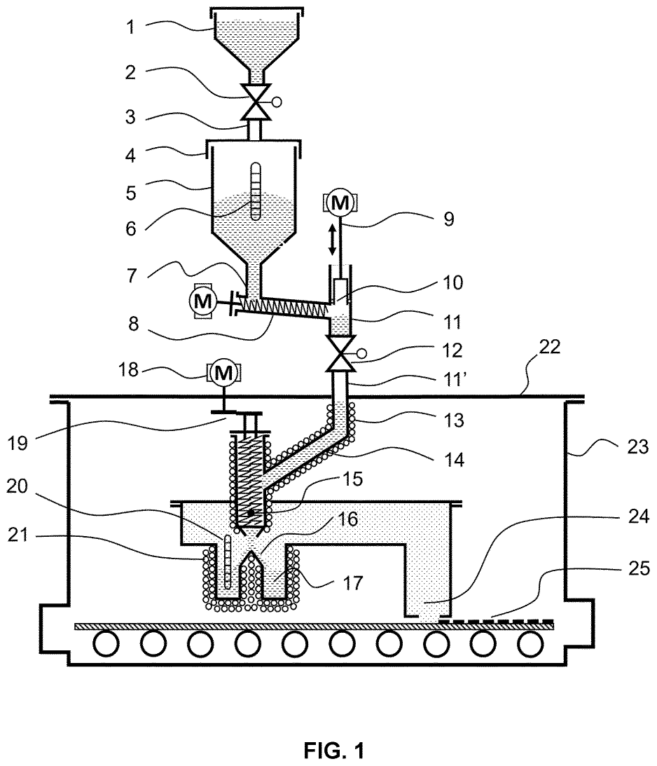

FIG. 1 shows a schematic cross-section of a CSS thin film deposition system having an automatic feeding device in accordance with the invention; and

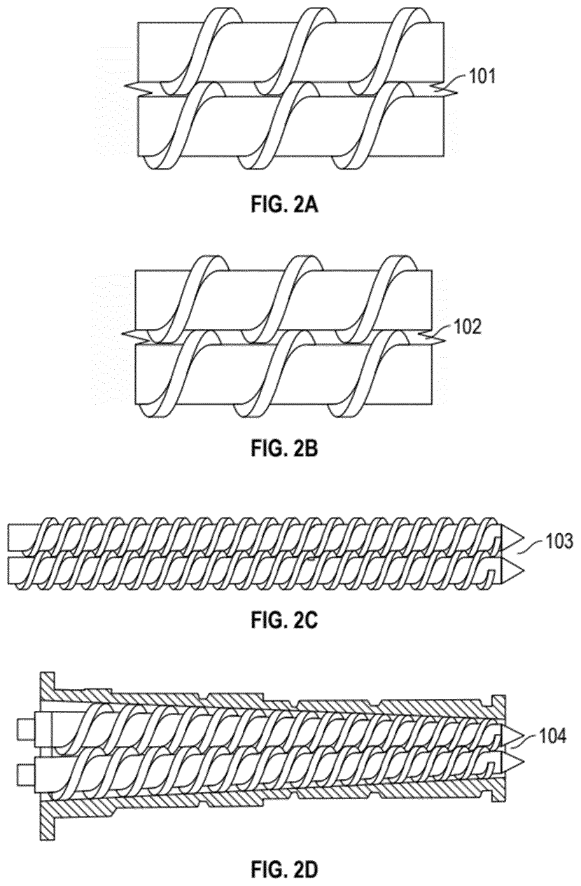

FIG. 2 shows schematic drawings of four twin-screw feeders.

The feeding system of FIG. 1 is assembled on the top-lid (22) of a thin-film CSS deposition chamber (23) and extends into the deposition chamber (23). The feeding system comprises a source-material hopper (5), a transfer system, and a two-screw feeder (15).

The source-material hopper has a lid (4) as well as a level sensor (6). The sensor detects the level of source material (e.g. powder or granules) inside the hopper. A funnel (1) is set on top of the hopper to assist with the filling of material into the hopper.

A first vacuum gate valve (2) is positioned between the funnel and the lid of the hopper. A vacuum pump (not shown in FIG. 1) is connected to the pumping tube (3) which connects the gate valve to the hopper.

The hopper is connected to a transfer system comprising a substantially horizontal barrel (8) and a substantially vertical tube (11). The substantially horizontal barrel (8) below the hopper contains a single screw feeder (7). The single-screw feeder moves the source material from the hopper into the vertical tube (11). The single-screw feeder is driven by a motor (M) and the rate at which the coating source material (e.g. powder or granules) is dispensed into the vertical tube (11) is monitored. This single-screw feeder acts to control the quantity and speed of material dispensed. As explained elsewhere, feedback from monitoring the level of coating source material in the crucible can be used to control feeder speed. The single-screw is made of steel and treated with a ta-C coating.

A second vacuum gate valve (12) is located in the vertical tube (11), just below the T-junction where the horizontal barrel (8) connects with the vertical tube (11). When the first vacuum gate valve (2) and the second vacuum gate valve (12) are closed, the region between the two valves (the hopper and the tubes) is pumped down, giving rise to a vacuum environment.

To prevent source material powder or granules from clogging the second vacuum gate valve (12), an O-ring seal (10) is positioned above the second vacuum gate valve. The O-ring seal is driven by a motor (M) attached to a cylinder piston (9). When the second vacuum gate valve is open, the O-ring seal is lowered to cover the valve and protect the valve from the powder or granules.

The hopper is made of stainless steel. The barrel is also made of stainless steel and protected by a coating. The barrel is made of 2 half-shells that are precisely joined together, and the mechanical structure of 2 shells supports a homogeneous thickness coating which is of advantage to transport the abrasive CdS or CdTe powder.

The vertical tube (11) extends into the thin film deposition chamber (23) and is connected to a vertical two-screw feeder (15), having screws made of nickel-based super alloy. The two-screw feeder (15) is located inside the vacuum deposition chamber (23). The two-screw feeder is connected to a motor (18/M) via a gear (19). The motor is positioned outside the deposition chamber on the top lid (22) of the chamber. One of the screws is driven by the motor (18) and rotated about its axis, and the second screw is driven by the first screw.

The size of the two-screw feeder (15) is optionally variable depending on the type of source material used and the dispensing rate needed. As explained elsewhere, feedback from monitoring the level of coating source material in the crucible is used to control feeder speed as this controls rate of coating source material feeding into the crucible.

FIG. 2 shows four schematic drawings of options for the two-screw feeder (15). As can be seen in all of (a) to (d) of FIG. 2 the two screws are intermeshing and counter-rotating, forming a self-cleaning twin screw feeder. The distance between the two screws is adjustable (note the difference between the arrangement of the screws 101 in FIG. 1 (a) and 102 in FIG. 1 (b)) and can be adjusted in order to adjust to various feeding material properties. There is a relatively small opening between the channels of the two rotating screws. Each rotation of the screws causes a fixed amount of source material to be displaced downward. The two screws may be arranged axis-parallel (103 in FIG. 2 (c)) or with an axis-angle (104 in FIG. 2 (d)) to further improve feeding accuracy for continuous feeding of different coating source materials with different properties.

Referring to FIG. 1, the lower opening of the two-screw feeder is positioned directly above the crucible (17) inside the deposition chamber. The crucible (17) comprises a central pin (16) and the opening of the two-screw feeder (15) is positioned directly above the central pin. There are sensors (20) attached to the crucible for detecting the level of source material inside the crucible and providing control feedback for feeding rate adjustment to maintain optimal conditions for vapour generation. Heating elements (21) are placed outside the crucible and surround the walls of the crucible. Heating elements (21) are also placed inside the central pin.

As the crucible is heated to 600-700° C., the two-screw feeder directly above the crucible reaches temperatures as high as 450-550° C.

Cooling systems (13) are wrapped around the tubes inside the deposition chamber to help to cool the tubes.

In use, the coating source materials (CdS powder and/or granules for a CdS coating, or alternatively CdTe powder and/or granules for a CdTe coating) are introduced into the large hopper (5) via the attached upper funnel (1) which sits on the lid of the hopper. There is a first vacuum gate valve (2) between the lower end of the funnel and the connection to the lid of the hopper. To add source material from an ambient room environment (e.g., temperature and humidity-controlled room) into the hopper, the second vacuum gate valve (12) is initially closed while the first vacuum gate valve (2) is open, allowing the pressure inside the hopper to reach atmospheric pressure. After a desired amount of source material powder or granules have been added into the hopper, the first vacuum gate valve (2) is closed.

The vacuum pump connected to the tube above the hopper is operated to pump the air out of the region between the first and second vacuum gate valves. The pressure is reduced to about 1 m Torr or 0.1 Pa.

When the pressure inside the hopper is about the same as the pressure in the deposition system, the second vacuum gate valve (12) is opened. The first vacuum gate valve (2) remains closed.

The source materials are pushed by the single screw feeder (7) inside the substantially horizontal barrel (8) and moved towards the vertical tube (11), where they are dispensed into the vertical tube.

When the second vacuum gate valve (12) is opened, source materials are able to enter the vertical tube (11′) and fall down the tube by gravity. To prevent source materials from sticking to the valve and clogging the valve, an O-ring seal (10) which stands by above the T-junction inside the vertical tube (11) is lowered to cover the valve (12), preventing source materials from coming into direct contact with the valve.

The amount of material entering the vertical tube is monitored by the horizontal single screw feeder. The motor of the single screw is optionally connected to another meter to calculate the amount of material dispensed per unit time.

The O-ring seal (10) is lifted and the second vacuum gate valve (12) is then closed when enough materials have entered a lower section of the vertical tube (11′).

The lower end of the vertical tube extends into the vacuum deposition chamber (23) where the crucible is located. The source materials enter the vertical two-screw feeder (15) via a tube (14) and a feed-port (not shown in FIG. 1) that opens into the middle section of the vertical feeder (15). The feeding of powder or granules into the feeder (15) is driven by gravity (no carrier gas is used in this feeding system).

There are vacuum pumps (not shown in FIG. 1) connected to the deposition chamber. The pressure inside the two-screw feeder is monitored and controlled so as to be about the same as that inside the vacuum deposition chamber.

The source materials are moved down the feeder by the twin, counter-rotating intermeshing screws and the source materials exit the lower end of the feeder and fall into the crucible (17) located inside the vapour deposition chamber (23). The crucible is placed directly below the exit of the two-screw feeder.

Vapour is guided to the opening area (24) of the deposition source, in order to continuously deposit a coating, optionally a multi-layer coating, onto a substrate (25), e.g. solar glass, by close-spaced sublimation (CSS).

The two-screw feeder functions to very accurately deliver a fine powder with grain size 50~150 μm with following feeding rates:
For CdS: the feeding rate is in the range of 0.065 to 0.095 gram per second.
For CdTe: the feeding rate is about 0.18 to 0.25 gram per second.

The two-screw feeder is found to work well in use, even when subjected to the highly elevated temperatures of the CSS source.

The temperature of the two-screw feeder during operation is about 450-550° C., while the crucible is at a higher temperature of about 600-700° C. As the two-screw feeder is at a lower temperature than the crucible, some of the source material vapour from the crucible gets deposited on the screws. In this event, the solid deposits are constantly removed by the mutual grinding action of the intermeshing screws. Thus, the screws are self-cleaning, preventing vapour from escaping the feeder and depositing in the transportation barrels.

The two-screw feeder is connected to a motor (18) and the rate of rotation of the feeder can also be adjusted based on feedback from sensor(s) (20).

The source materials fall onto the central pin (16) of the crucible (17) and slide down the sides of the pin. Inside the central pin there is a heater which helps to establish a thermal equilibrium for heating, generating a steady rate of vapour production.

Resistive sensors (20) are placed on the crucible to monitor the level of materials inside the crucible. The upstream feeding can be controlled by controlling the dispensing rate from the horizonal single screw (7), the opening and closing of the second vacuum gate valve (12), and the rotation speed of the two-screw feeder (15). These control mechanisms used in combination help to maintain a stable level of materials inside the crucible and a long-term stable coating rate is realized with the apparatus effectively in continuous operation.

1. An apparatus for continuously depositing a coating, optionally a multi-layer coating, onto a substrate by close-spaced sublimation (CSS) of coating source material, comprising
a CSS source, for depositing the coating onto the substrate, and
a feeder system for feeding coating source material into the CSS source, wherein
the feeder system comprises a self-cleaning twin screw feeder arranged to feed the coating source material into the CSS source during deposition of the coating.

2. The apparatus according to claim 1, wherein the screw feeder is located within a sealable portion of the apparatus, wherein in use that portion can be evacuated, and the screw feeder operated under vacuum.

3. The apparatus according to claim 1, wherein the feeder system comprises a hopper for source material storage, upstream of the screw feeder, wherein the hopper is located within a sealable portion of the apparatus, wherein in use that portion can be evacuated, and the hopper can be under vacuum.

4. The apparatus according to claim 3, comprising the hopper, a first screw feeder and a second screw feeder, wherein the first screw feeder feeds source material from the hopper to the second screw feeder and the second screw feeder feeds source material into the CSS source.

5. The apparatus according to claim 1, comprising in order:
a first vacuum gate,
a hopper for storage of coating source material,
a first screw feeder, preferably a single screw feeder,
a second vacuum gate,
a second screw feeder, preferably a twin screw feeder, and
an output from the second screw feeder,
wherein
the apparatus further comprises a pump to pump down the apparatus between the first and second vacuum gates.

6. The apparatus according to claim 1, further comprising a crucible and wherein an output from the second screw feeder is for delivery of source material into the crucible.

7. The apparatus according to claim 6, wherein the crucible comprises a central pin and the output delivers source material onto the central pin.

8. The apparatus according to claim 7, wherein the central pin of the crucible comprises a heating element.

9. The apparatus according to claim 6, wherein the crucible comprises one or more sensors to detect the level of source material therein.

10. The apparatus according to claim 9, further comprising a feed control system that varies the rate of feeding source material into the crucible by the feeder system based on input from the crucible level sensor(s).

11. The apparatus according to claim 1, comprising a hopper for source material storage and further comprising one or more sensors in the hopper to detect level of source material therein.

12. The apparatus according to claim 1, for depositing a coating comprising a cadmium compound.

13. A method of depositing a cadmium-containing coating, comprising operating an apparatus according to claim 1, wherein the method comprises feeding a cadmium-containing source material into the feeder system of the apparatus and depositing the cadmium-containing source material onto a substrate by CSS.

14. A method of depositing a cadmium-containing coating, comprising operating an apparatus according to claim 9, comprising
monitoring input from the one or more sensors in the crucible, and
using the feed control system to adjust the rate of feeding into the crucible by the feeder system, based on the input from the one or more sensors in the crucible, to maintain a predetermined rate of deposition by the CSS source.
